(19) United States
(12) Patent Application Publication
(10) Pub. No.: US 2022/0319817 A1
(43) Pub. Date: Oct. 6, 2022

(54) PLASMA PROCESSING SYSTEM WITH FARADAY SHIELDING DEVICE

(71) Applicant: JIANGSU LEUVEN INSTRUMENTS CO., LTD, Jiangsu (CN)

(72) Inventors: Xuedong LI, Jiangsu (CN); Xiaobo LIU, Jiangsu (CN); Dongdong HU, Jiangsu (CN); Haiyang LIU, Jiangsu (CN); Hongbo SUN, Jiangsu (CN); Kaidong XU, Jiangsu (CN); Lu CHEN, Jiangsu (CN)

(73) Assignee: JIANGSU LEUVEN INSTRUMENTS CO., LTD, Jiangsu (CN)

(21) Appl. No.: 17/626,498

(22) PCT Filed: Feb. 26, 2020
(86) PCT No.: PCT/CN2020/076752

§ 371 Date: Jan. 12, 2022

(30) Foreign Application Priority Data
Jul. 19, 2019 (CN) 201910654770.0

(51) Int. Cl. H01J 37/32

(52) U.S. Cl. CPC H01J 37/32651; H01J 37/3244; H01J 37/32119; H01J 37/32532; H01J 2237/026

(57) ABSTRACT

Disclosed is a plasma processing system with a faraday shielding device. The plasma processing system comprises a reaction chamber, and a faraday shielding device and an air inlet nozzle which are located on the reaction chamber. The air inlet nozzle penetrates through the faraday shielding device to introduce process gas into the reaction chamber. The air inlet nozzle is made of a conductive material, and the air inlet nozzle is electrically connected to the faraday shielding device. According to the plasma processing system, the air inlet nozzle made of the conductive material is electrically connected to the faraday shielding device, when the cleaning process is carried out, reaction gas of the cleaning process in the projection area of the air inlet nozzle is also electrically isolated, the reaction gas of the cleaning process forms a capacitive coupling plasma in the whole region below a dielectric window.

### TECHNICAL FIELD

The present invention belongs to the field of semiconductor etching technologies, and in particular, to a plasma processing system with a Faraday shielding device.

### DESCRIPTION OF RELATED ART

Currently, nonvolatile materials such as Pt, Ru, Ir, NiFe, and Au are mainly dry etched by inductively coupled plasma (ICP). ICP is usually generated by a coil that is placed outside a plasma processing chamber and is adjacent to a dielectric window, and process gas inside the chamber is ignited to form the plasma. During a dry etching process of a nonvolatile material, the vapor pressure of reaction products is low, making it difficult to pump away the reaction products by a vacuum pump. As a result, the reaction products are deposited on inner walls of the dielectric window and another plasma processing chamber. Particle contamination is caused, and the process drifts over time and becomes less repeatable.

With the continuous development and increasing integration of the third generation memory, that is, magnetoresistive random access memory (MRAM), in recent years, the demand for dry etching of new nonvolatile materials such as metal gate materials (for example, Mo and Ta) and high-k gate dielectric materials (for example, Al₂O₃, HfO₂, and ZrO₂) keeps increasing, and it becomes very necessary to solve sidewall deposition and particle contamination that occur during dry etching of the nonvolatile materials while improving the efficiency of a cleaning process in a plasma processing chamber.

A Faraday shielding device is placed between a radio frequency coil and a dielectric window, so that the erosion of walls of a chamber by ions induced by a radio frequency electric field can be reduced. Shielding power is coupled into the Faraday shielding device, and an appropriate cleaning process is selected, so that inner walls of the dielectric window and the chamber can be cleaned, thereby avoiding problems such as particle contamination, instable radio frequency, and process window drift caused by the deposition of reaction products on the inner walls of the dielectric window and the chamber. A gas inlet nozzle that introduces process gas into a reaction chamber is provided in the Faraday shielding device. However, the dielectric window around the gas inlet nozzle cannot be cleaned in the Faraday shielding device in the prior art, resulting in local deposition of particles. If the particles fall off and fall onto the surface of a wafer, the surface of the wafer suffers from reduced uniformity and defects, and the life cycle of a plasma processing system is reduced.

### SUMMARY

To solve the foregoing problem, the present invention provides a plasma processing system with a Faraday shielding device, so that a dielectric window in an area surrounding a gas inlet nozzle can be cleaned, and the failure rate of the plasma processing system is reduced.

Technical Solutions

The present invention provides a plasma processing system with a Faraday shielding device, including a reaction chamber and a Faraday shielding device and a gas inlet nozzle that are located on the reaction chamber, where the gas inlet nozzle passes through the Faraday shielding device to introduce process gas into the reaction chamber; and the gas inlet nozzle is made of a conductive material, and the gas inlet nozzle is conductively connected to the Faraday shielding device.

Further, a gas inlet side of the gas inlet nozzle is connected to a gas inlet conduit; and the gas inlet nozzle is connected to the gas inlet conduit in an insulated manner.

Further, a through hole for the gas inlet nozzle to pass through is provided in the Faraday shielding device; an inner ring of the through hole is conductively connected to the gas inlet nozzle; and a conducting wire for supplying power to the Faraday shielding device passes through the gas inlet nozzle for electrical connection to the Faraday shielding device.

Further, the through hole is located at the center of the Faraday shielding device.

Further, the Faraday shielding device includes a plurality of petal-shaped components that are centrosymmetric and are arranged at intervals; and an end of each petal-shaped component close to the center of symmetry is connected to the gas inlet nozzle.

Further, the plasma processing system further includes a dielectric window located at an end of the reaction chamber, where an inner wall of the dielectric window is located between the reaction chamber and the Faraday shielding device; and the process gas sprayed from the gas inlet nozzle passes through the Faraday shielding device and the dielectric window to be introduced into the reaction chamber.

Further, a gas outlet port of the gas inlet nozzle is placed on an outer side of the inner wall of the dielectric window.

Further, an extension gas inlet tube made of an insulating material is installed at the gas outlet port of the gas inlet nozzle; a plurality of first gas inlet holes in communication with the gas inlet nozzle are provided in the extension gas inlet tube; the extension gas inlet tube passes through the dielectric window and is in communication with the reaction chamber through the plurality of first gas inlet holes; and the inner wall of the dielectric window is located between the gas outlet port of the gas inlet nozzle and the reaction chamber.

Further, the gas outlet port of the gas inlet nozzle is inserted in the dielectric window, and the gas outlet port is located between the inner wall and an outer wall of the dielectric window; and a plurality of second gas inlet holes in communication with the gas outlet port and the reaction chamber are provided in the dielectric window.

Further, a corrosion-resistant layer is provided on an inner wall of the gas inlet nozzle.

### Beneficial Effects

In the present invention, the gas inlet nozzle made of the conductive material is conductively connected to the Faraday shielding device. During a cleaning process, cleaning process reaction gas in a projection area of the gas inlet nozzle is also ionized, the cleaning process reaction gas forms capacitively coupled plasma in the whole area below the dielectric window, and the dielectric window in an area surrounding the gas inlet nozzle can be cleaned, so that all around cleaning of the inner wall of the dielectric window is implemented, and the failure rate of the plasma processing system is reduced.

### BRIEF DESCRIPTION OF THE DRAWINGS

FIG. 1 is a schematic structural diagram according to the present invention;

FIG. 2 is a top view of a Faraday shielding device according to the present invention;

FIG. 3 is a process flowchart of an application according to the present invention;

FIG. 4 is a schematic diagram of an arrangement of first gas inlet holes of an extension gas inlet tube according to the present invention; and

FIG. 5 is a schematic diagram of another arrangement of first gas inlet holes of an extension gas inlet tube according to the present invention.

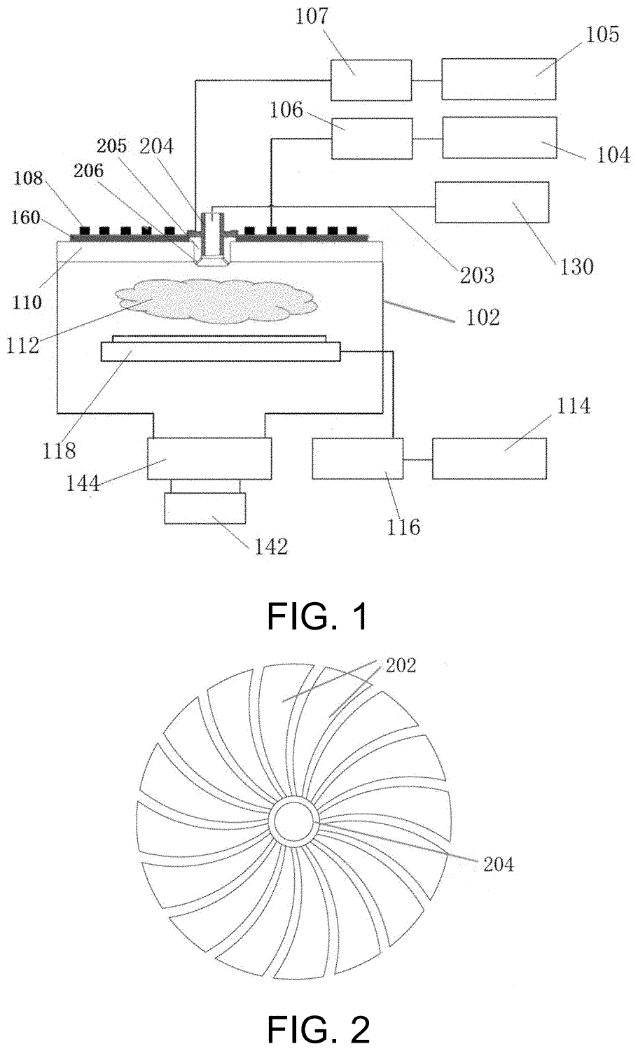

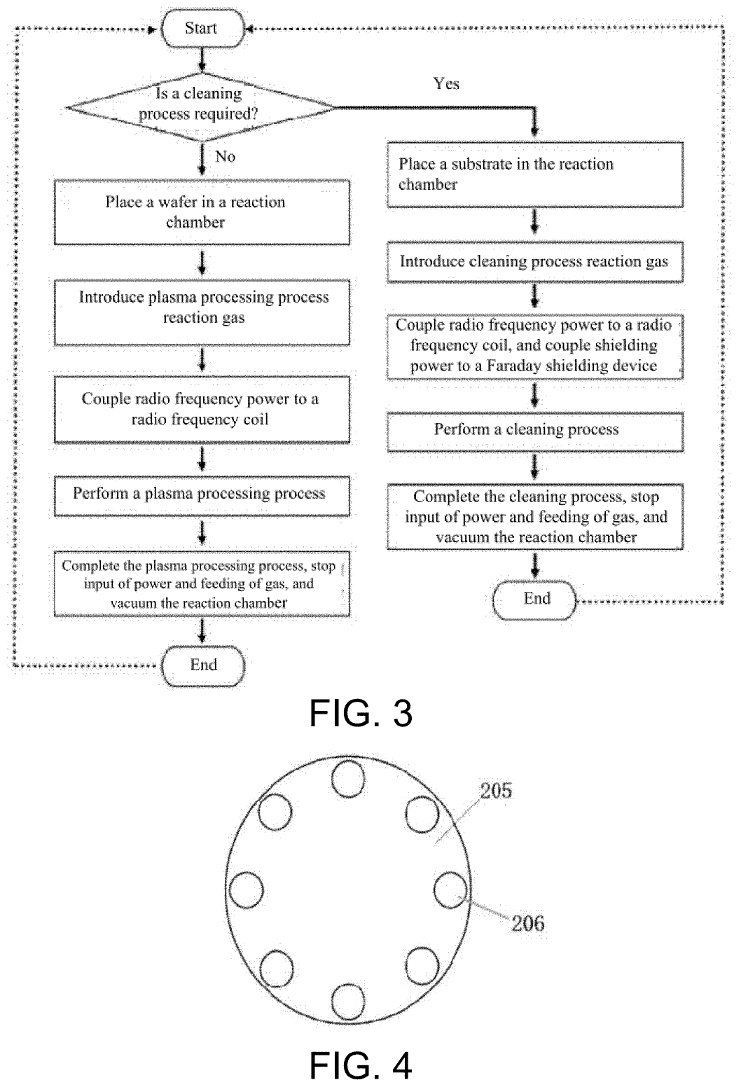

### DESCRIPTION OF THE EMBODIMENTS

The present invention relates to a plasma processing system with a Faraday shielding device. The plasma processing system includes a reaction chamber 102, a dielectric window 110 located at an end of the reaction chamber 102, a Faraday shielding device 160, and a gas inlet nozzle 204. An inner wall of the dielectric window 110 is located between the reaction chamber 102 and the Faraday shielding device 160. Specifically, the Faraday shielding device 160 may be placed on an outer wall of the dielectric window 110, or the dielectric window 110 is wrapped on an outer side of the Faraday shielding device 160. Process gas sprayed from the gas inlet nozzle 204 passes through the dielectric window 110 and the Faraday shielding device 160 to be introduced into the reaction chamber 102.

The gas inlet nozzle 204 is made of a conductive material. The conductive material may be, for example, Al, Cu, gold plated stainless steel or another conductive material that can be used for radio frequency conduction. The gas inlet nozzle 204 is conductively connected to the Faraday shielding device 160.

A gas source 130 is connected to the gas inlet nozzle 204 by a gas inlet conduit 203. To avoid electrical conduction, the gas inlet nozzle 204 is connected to the gas inlet conduit 203 in an insulated manner. Specifically, the gas inlet conduit 203 made of an insulating material may be used, or a part where the gas inlet nozzle 204 is connected to the metal gas inlet conduit 203 needs to be isolated by an insulating tube. To prevent the gas inlet nozzle 204 from corrosion by gas, the inner wall of the gas inlet nozzle 204 may be plated with a corrosion-resistant coating or nested with an inner tube made of another corrosion-resistant material such as ceramics.

Process gas may be ionized inside the gas inlet nozzle 204 to form plasma to cause ignition of the plasma, causing damage to an inner surface of the gas inlet nozzle 204 to produce particles. To avoid this, in this embodiment, a gas outlet port of the gas inlet nozzle 204 is placed on an outer side of the inner wall of the dielectric window 110. A distance between the gas outlet port of the gas inlet nozzle 204 and the inner wall of the dielectric window 110 is adjusted, so that a cleaning rate in a projection area of the gas inlet nozzle 204 on the dielectric window 110 may be adjusted. When the gas outlet port of the gas inlet nozzle 204 is closer to the inner wall of the dielectric window 110, the cleaning effect of the dielectric window in the projection area of the gas inlet nozzle 204 is better.

Specifically, there are two embodiments:

Embodiment 1: An extension gas inlet tube 205 made of an insulating material is installed in communication at the gas outlet port of the gas inlet nozzle 204. A plurality of first gas inlet holes 206 are provided in the extension gas inlet tube 205. The extension gas inlet tube 205 passes through the dielectric window 110 and is in communication with the reaction chamber 102 through the plurality of first gas inlet holes 206. The inner wall of the dielectric window 110 is located between the gas outlet port of the gas inlet nozzle 204 and the reaction chamber 102. By the extension gas inlet tube 205, the gas outlet port of the gas inlet nozzle 204 may be in communication with the reaction chamber 102 without extending into the reaction chamber 102. The position of the gas outlet port of the gas inlet nozzle 204 may be adjusted as required, and may be located between the inner wall and the outer wall of the dielectric window 110 or may be located on an outer side of the outer wall of the dielectric window 110. In addition, the disassembly and repair are facilitated when a fault such as clogging of the first gas inlet holes 206 occurs in the extension gas inlet tube 205.

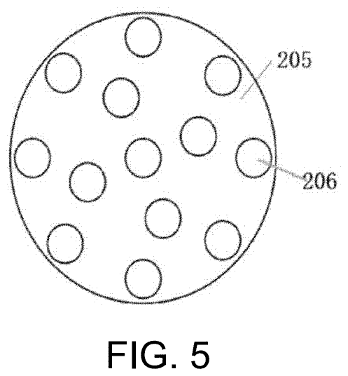

As shown in FIG. 4 and FIG. 5, preferably, the plurality of first gas inlet holes 206 are arranged along an outer edge of an orthographic projection area of the gas outlet port or the plurality of first gas inlet holes 206 are uniformly arranged in the orthographic projection area of the gas outlet port.

Embodiment 2: The gas outlet port of the gas inlet nozzle 204 is inserted in the dielectric window 110, and the gas outlet port is located between the inner wall and the outer wall of the dielectric window 110. A plurality of second gas inlet holes in communication with the gas outlet port and the reaction chamber 102 are provided in the dielectric window 110. Because holes need to be opened in the dielectric window 110 in Embodiment 2, the machining cost is higher than that in Embodiment 1, and repair is inconvenient when a fault such clogging occurs in the second gas inlet holes.

The Faraday shielding device 160 of the present invention includes a plurality of petal-shaped components 202 that are centrosymmetric and are arranged at intervals. A through hole is provided at an end of each of the plurality of petal-shaped components 202 close to the center of symmetry. The gas inlet nozzle 204 passes through the through hole. An inner ring of the through hole is conductively connected to the gas inlet nozzle 204. Specifically, the inner ring of the through hole and the gas inlet nozzle 204 are preferably integrally formed or may be separately machined and threadedly tightened together.

The present invention further includes a shielding power source 105 configured to supply power to the Faraday shielding device 160 and a shielding matching network 107. The shielding power source 105 is tuned by the shielding matching network 107 and is then connected to the gas inlet nozzle 204 by a conducting wire to supply power to the Faraday shielding device 160. Such a structure allows the shielding power source 105 to be equipotentially connected to the plurality of petal-shaped components 202, so that the capacitive coupling between the plurality of petal-shaped components 202 and the plasma is more uniform.

The present invention further includes a radio frequency coil 108, an excitation radio frequency power source 104, and an excitation matching network 106. The excitation radio frequency power source 104 is tuned by the excitation matching network 106 to supply power to the radio frequency coil 108. The radio frequency coil 108 is located on the outer wall of the dielectric window 110. The Faraday shielding device 160 is located between the radio frequency coil 108 and the inner wall of the dielectric window 110.

An electrode 118 is further disposed in the reaction chamber 102. A bias matching network 116 supplies power to the electrode 118 through a bias radio frequency power source 114.

The shielding power source 105, the excitation radio frequency power source 104 and the bias radio frequency power source 114 may be set to a specific frequency such as 400 KHz, 2 MHz, 13.56 MHz, 27 MHz, 60 MHz, 2.54 GHz or a combination of the foregoing frequencies.

A wafer or a substrate is placed on the electrode 118.

A pressure control valve 142 and a vacuum pump 144 are further disposed on the reaction chamber 102, and are configured to pump away gas in the reaction chamber 102, to maintain the reaction chamber 102 at a specific pressure and remove excess gas and reaction byproducts in the reaction chamber 102.

During a plasma processing process, the wafer is placed in the reaction chamber 102. The gas inlet nozzle 204 introduces plasma processing process reaction gas such as fluorine into the reaction chamber 102. The specific pressure in the reaction chamber 102 is maintained by the pressure control valve 142 and the vacuum pump 144. The excitation radio frequency power source 104 is tuned by the excitation matching network 106 to supply power to the radio frequency coil 108. Plasma 112 is generated in the reaction chamber 102 through inductive coupling to perform the plasma processing process on the wafer. After the plasma processing process is completed, input of radio frequency power is stopped, and feeding of the plasma processing process reaction gas is stopped.

When a cleaning process is required, the substrate is placed in the reaction chamber 102. The gas inlet nozzle 204 introduces cleaning process reaction gas such as argon, oxygen, and nitrogen trifluoride into the reaction chamber 102. The specific pressure in the reaction chamber 102 is maintained by the pressure control valve 142 and the vacuum pump 144. The excitation radio frequency power source 104 is tuned by the excitation matching network 106 to supply power to the radio frequency coil 108. The shielding power source 105 is tuned by the shielding matching network 107 to supply power to the Faraday shielding device 160. Power from the radio frequency coil 108 and the Faraday shielding device 160 generates argon ions or the like, which are sputtered on the inner wall of the dielectric window 110 to clean the dielectric window 110. Because the gas inlet nozzle 204 is conductively connected to the Faraday shielding device 160, the cleaning process reaction gas in a projection area of the gas inlet nozzle 204 is also ionized, argon ions or the like are generated, and the cleaning process reaction gas forms capacitively coupled plasma in the whole area below the dielectric window 110, so that all around cleaning of the inner wall of the dielectric window 110 is implemented, and the failure rate of the plasma processing system is reduced. After the cleaning process is completed, input of radio frequency power is stopped, and feeding of the cleaning process reaction gas is stopped.

1. A plasma processing system with a Faraday shielding device, comprising a reaction chamber and a Faraday shielding device and a gas inlet nozzle that are located on the reaction chamber, wherein the gas inlet nozzle passes through the Faraday shielding device to introduce process gas into the reaction chamber; wherein the gas inlet nozzle is made of a conductive material, and the gas inlet nozzle is conductively connected to the Faraday shielding device.

2. The plasma processing system with a Faraday shielding device according to claim 1, wherein a gas inlet side of the gas inlet nozzle is connected to a gas inlet conduit; and the gas inlet nozzle is connected to the gas inlet conduit in an insulated manner.

3. The plasma processing system with a Faraday shielding device according to claim 2, wherein a through hole for the gas inlet nozzle to pass through is provided in the Faraday shielding device; an inner ring of the through hole is conductively connected to the gas inlet nozzle; and a conducting wire for supplying power to the Faraday shielding device passes through the gas inlet nozzle for electrical connection to the Faraday shielding device.

4. The plasma processing system with a Faraday shielding device according to claim 3, wherein the through hole is located at the center of the Faraday shielding device.

5. The plasma processing system with a Faraday shielding device according to claim 3, wherein the Faraday shielding device comprises a plurality of petal-shaped components that are centrosymmetric and are arranged at intervals; and an end of each petal-shaped component close to the center of symmetry is connected to the gas inlet nozzle.

6. The plasma processing system with a Faraday shielding device according to claim 1, is characterized by: further comprising a dielectric window located at an end of the reaction chamber, wherein an inner wall of the dielectric window is located between the reaction chamber and the Faraday shielding device; and the process gas sprayed from the gas inlet nozzle passes through the Faraday shielding device and the dielectric window to be introduced into the reaction chamber.

7. The plasma processing system with a Faraday shielding device according to claim 6, wherein a gas outlet port of the gas inlet nozzle is placed on an outer side of the inner wall of the dielectric window.

8. The plasma processing system with a Faraday shielding device according to claim 7, wherein an extension gas inlet tube made of an insulating material is installed in communication at the gas outlet port of the gas inlet nozzle; a plurality of first gas inlet holes are provided in the extension gas inlet tube; the extension gas inlet tube passes through the dielectric window and is in communication with the reaction chamber through the plurality of first gas inlet holes; and the inner wall of the dielectric window is located between the gas outlet port of the gas inlet nozzle and the reaction chamber.

9. The plasma processing system with a Faraday shielding device according to claim 7, wherein the gas outlet port of the gas inlet nozzle is inserted in the dielectric window, and the gas outlet port is located between the inner wall and an outer wall of the dielectric window; and a plurality of second gas inlet holes in communication with the gas outlet port and the reaction chamber are provided in the dielectric window.

10. The plasma processing system with a Faraday shielding device according to claim 1, wherein a corrosion-resistant layer is provided on an inner wall of the gas inlet nozzle.

11. The plasma processing system with a Faraday shielding device according to claim 2, further comprising a dielectric window located at an end of the reaction chamber, wherein an inner wall of the dielectric window is located between the reaction chamber and the Faraday shielding device; and the process gas sprayed from the gas inlet nozzle passes through the Faraday shielding device and the dielectric window to be introduced into the reaction chamber.

12. The plasma processing system with a Faraday shielding device according to claim 3, further comprising a dielectric window located at an end of the reaction chamber, wherein an inner wall of the dielectric window is located between the reaction chamber and the Faraday shielding device; and the process gas sprayed from the gas inlet nozzle passes through the Faraday shielding device and the dielectric window to be introduced into the reaction chamber.

13. The plasma processing system with a Faraday shielding device according to claim 4, further comprising a dielectric window located at an end of the reaction chamber, wherein an inner wall of the dielectric window is located between the reaction chamber and the Faraday shielding device; and the process gas sprayed from the gas inlet nozzle passes through the Faraday shielding device and the dielectric window to be introduced into the reaction chamber.

14. The plasma processing system with a Faraday shielding device according to claim 5, further comprising a dielectric window located at an end of the reaction chamber, wherein an inner wall of the dielectric window is located between the reaction chamber and the Faraday shielding device; and the process gas sprayed from the gas inlet nozzle passes through the Faraday shielding device and the dielectric window to be introduced into the reaction chamber.
